(19) United States
(12) Patent Application Publication
(10) Pub. No.: US 2014/0311530 A1
(43) Pub. Date: Oct. 23, 2014

(54) SUBSTRATE PROCESSING METHOD AND TEMPLATE

(71) Applicant: TOKYO ELECTRON LIMITED, Tokyo (JP)

(72) Inventors: Haruo Iwatsu, Kumamoto (JP); Takayuki Toshima, Kumamoto (JP); Kazuo Sakamoto, Kumamoto (JP)

(73) Assignee: TOKYO ELECTRON LIMITED, Tokyo (JP)

(21) Appl. No.: 14/358,847

(22) PCT Filed: Oct. 22, 2012
(86) PCT No.: PCT/JP2012/077209

§ 371 Date: May 16, 2014

(30) Foreign Application Priority Data
Nov. 18, 2011 (JP) 2011-252214

(51) Int. Cl. H01L 21/768

(52) U.S. Cl. CPC H01L 21/76897; H01L 21/76826
USPC 134/26; 428/131

(57) ABSTRACT

A substrate processing method of performing a predetermined processing by supplying a processing liquid to a processing region on a surface of a substrate, includes: supplying an alignment liquid to an alignment region on the surface of the substrate formed at a position different from that of the processing region; aligning a template disposed facing the substrate and including a processing liquid passage configured to pass the processing liquid and an alignment liquid passage configured to pass the alignment liquid, with respect to the substrate with the alignment liquid supplied to the alignment region such that the processing liquid passage is positioned above the processing region; and performing the predetermined processing on the substrate by supplying the processing liquid to the processing region through the processing liquid passage.

### TECHNICAL FIELD

The present disclosure relates to a substrate processing method of performing a predetermined processing by supplying a processing liquid to a processing region on a surface of a substrate, and a template for use in the substrate processing method.

### BACKGROUND

In manufacturing semiconductor devices (hereinafter, referred to as “devices”), the devices have recently been advanced in high integration. Under such situation, in a case where products are commercialized by arranging a plurality of highly integrated devices in a horizontal plane and connecting the devices with wiring, it is concerned that the wiring length is increased and thus, the wiring resistance and the wiring delay are increased.

Accordingly, a three-dimensional (3D) integration technique for three-dimensionally stacking devices has been proposed. In the 3D integration technique, a plurality of electrodes so-called through silicon vias (TSVs) having a minute diameter of, for example, 100 μm or less, is formed through a semiconductor wafer (hereinafter, referred to as a “wafer”) having a plurality of electronic circuits formed on its surface. And, the vertically stacked devices (wafers), are electrically connected to each other through the through silicon vias (Patent Document 1).

The above-mentioned through silicon vias need to be formed with high positional accuracy in order to properly stack the devices. Accordingly, a plating method disclosed in, for example, Patent Document 2 may be used for formation of the through silicon vias. In the method, plating liquid is applied onto a surface of a wafer, tips of microprobes are attached to the applied plating liquid, and an electric current is applied from the microprobes to the wafer, thereby controlling a plating region.

Further, it has been proposed to use a template in which a plurality of openings is formed at positions corresponding to predetermined positions of a wafer in order to perform plating at the predetermined positions of the wafer (the positions where through silicon vias are formed) and includes plating liquid passages in communication with the openings (Patent Document 3). In the method, when the template is disposed on the wafer, and the plating liquid is supplied to the wafer through the passages and the openings, the plating liquid is supplied to the predetermined positions.

### PRIOR ART DOCUMENT

### Patent Document

Patent Document 1: Japanese Patent Laid-Open Publication No. 2009-004722

Patent Document 2: Japanese Patent Laid-Open Publication No. 2008-280558

Patent Document 3: Japanese Patent Laid-Open Publication No. 2011-174140

### DISCLOSURE OF THE INVENTION

### Problems to be Solved

However, in the method of Patent Document 2, when a plurality of minute through silicon vias is formed with high positional accuracy, it is required to align the microprobes on a probe card with high positional accuracy. In practice, however, it is technically difficult to align the microprobes with high positional accuracy. Therefore, a processing liquid such as a plating liquid may not be supplied to a proper position, and thus, a proper processing may not be performed at a predetermined position.

Further, in the method of Patent Document 3, when the plating liquid is supplied to the wafer through the template, it is required to align the template and the wafer, but the alignment is performed, for example, by a mechanical moving mechanism. In this case, since a plurality of minute through silicon vias is formed on the wafer, it is difficult to align all the openings at proper positions on the wafer. Therefore, a processing liquid such as the plating liquid may not be supplied to a proper position, and thus, a proper processing cannot be performed at a predetermined position.

The present disclosure has been made in consideration of such problems and an object of the present disclosure is to properly supply a processing liquid to a predetermined position of a wafer with high positional accuracy and process the substrate.

### Means to Solve the Problems

In order to achieve the object, the present disclosure provides a substrate processing method of performing a predetermined processing by supplying a processing liquid to a processing region on a surface of a substrate, the method including: supplying an alignment liquid to an alignment region on the surface of the substrate formed at a position different from that of the processing region; aligning a template disposed facing the substrate and including a processing liquid passage configured to pass the processing liquid and an alignment liquid passage configured to pass the alignment liquid, with respect to the substrate with the alignment liquid supplied to the alignment region such that the processing liquid passage is positioned above the processing region; and performing the predetermined processing on the substrate by supplying the processing liquid to the processing region through the processing liquid passage.

According to the present disclosure, before supplying the processing liquid to the processing region of the substrate, the template is aligned with respect to the substrate with the alignment liquid supplied to the alignment region of the substrate in the aligning step. In the step of aligning the template, the alignment liquid in the alignment region is filled between the template and the substrate, and restoring force acts on the template by surface tension of the alignment liquid. By the restoring force, the template is moved such that the processing liquid passage is aligned above the processing region, and the alignment of the template and the substrate is performed with high accuracy. As a result, the processing liquid may be properly supplied to a predetermined position of the substrate, that is, to the processing region through the processing liquid passage with high positional accuracy in the subsequent step of performing the predetermined processing. Furthermore, since the step of aligning the template is performed with the alignment liquid which is a separate component from the processing liquid, even in a case where the area of the processing region is small and the position of the processing liquid passage of the template does not correspond to the processing region of the substrate prior to the step of aligning the template, the alignment of the template and the substrate may be properly performed. As described above, according to the present disclosure, the processing liquid may be properly supplied to a predetermined position of the substrate with high positional accuracy and the substrate may be properly processed using the processing liquid.

According to another aspect, the present disclosure provides a template for use in supplying a processing liquid to a processing region on a surface of a substrate, the template including: a processing liquid passage formed through the template in a thickness direction and configured to pass the processing liquid; and an alignment liquid passage formed through the template in the thickness direction and configured to pass an alignment liquid that is supplied to an alignment region on the surface of the substrate which is formed at a position different from that of the processing region so as to align the template with respect to the substrate.

### Effect of the Invention

According to the present disclosure, a processing liquid may be supplied to a predetermined position of a substrate with high positional accuracy such that the substrate may be properly processed with the processing liquid.

### BRIEF DESCRIPTION OF THE DRAWINGS

FIG. 1 is a longitudinal cross-sectional view illustrating a schematic configuration of a wafer processing apparatus for performing a wafer processing method according to an exemplary embodiment.

FIG. 2 is a longitudinal cross-sectional view illustrating a schematic configuration of a wafer.

FIG. 3 is a plan view of the schematic configuration of the wafer.

FIG. 4 is an explanatory view illustrating a schematic configuration of a template.

FIG. 5 is a longitudinal cross-sectional view illustrating the schematic configuration of the template.

FIG. 6 is a plan view illustrating a schematic configuration of a front surface of the template.

FIG. 7 is a plan view illustrating a schematic configuration of a rear surface of the template.

FIG. 8 is a flowchart illustrating main steps of the wafer processing.

FIGS. 9A to 9G are explanatory views schematically illustrating a state of the template and the wafer in each step of the wafer processing. FIG. 9A illustrates a state where deionized water is supplied to an alignment region of the wafer. FIG. 9B illustrates a state where the template is disposed above the wafer. FIG. 9C illustrates a state where alignment of the template and the wafer is performed. FIG. 9D illustrates a state where the template is moved down. FIG. 9E illustrates a state where a plating liquid is supplied to a plating liquid passage. FIG. 9F illustrates a state where the plating liquid is filled between the template and the wafer. FIG. 9G illustrates a state where a bump is formed on a through silicon via.

FIG. 10 is a longitudinal cross-sectional view illustrating a schematic configuration of a wafer according to another exemplary embodiment.

FIG. 11 is a longitudinal cross-sectional view illustrating a schematic configuration of a template according to another exemplary embodiment.

FIG. 12 is a longitudinal cross-sectional view illustrating a schematic configuration of a wafer according to still another exemplary embodiment.

FIG. 13 is a longitudinal cross-sectional view illustrating a schematic configuration of a template according to still another exemplary embodiment.

FIG. 14 is a longitudinal cross-sectional view illustrating a schematic configuration of a wafer according to yet another exemplary embodiment.

FIG. 15 is a longitudinal cross-sectional view illustrating a schematic configuration of a template according to yet another exemplary embodiment.

FIG. 16 is a longitudinal cross-sectional view illustrating a schematic configuration of a wafer according to still yet another exemplary embodiment.

FIG. 17 is a longitudinal cross-sectional view illustrating a schematic configuration of a template according to still yet another exemplary embodiment.

FIG. 18 is a longitudinal cross-sectional view illustrating a schematic configuration of a wafer according to still yet another exemplary embodiment.

FIG. 19 is a longitudinal cross-sectional view illustrating a schematic configuration of a template according to still yet another exemplary embodiment.

FIGS. 20A and 20B are explanatory views schematically illustrating a state of the template and the wafer in each wafer processing step according to another exemplary embodiment. FIG. 20A illustrates a state where the template is disposed above the wafer. FIG. 20B illustrates a state where the template is moved down.

FIGS. 21A to 21C are explanatory views schematically illustrating a state of the template and the wafer in each wafer processing step according to still another exemplary embodiment. FIG. 21A illustrates a state where the template is disposed above the wafer. FIG. 21B illustrates a state where deionized water is supplied to an alignment region of the wafer. FIG. 21C illustrates a state where the alignment of the template and the wafer is performed.

FIGS. 22A and 22B are explanatory views schematically illustrating a state of the template and the wafer in each wafer processing step according to yet another exemplary embodiment. FIG. 22A illustrates a state where the template is disposed at an upper side of the wafer. FIG. 22B illustrates a state where deionized water is supplied to an alignment region of the wafer.

### DETAILED DESCRIPTION TO EXECUTE THE INVENTION

Hereinafter, exemplary embodiments of the present disclosure will be described. Further, in drawings used in the following description, the dimension of each component does not necessarily correspond to the actual dimension thereof in order to prioritize ease of understanding of the technology.

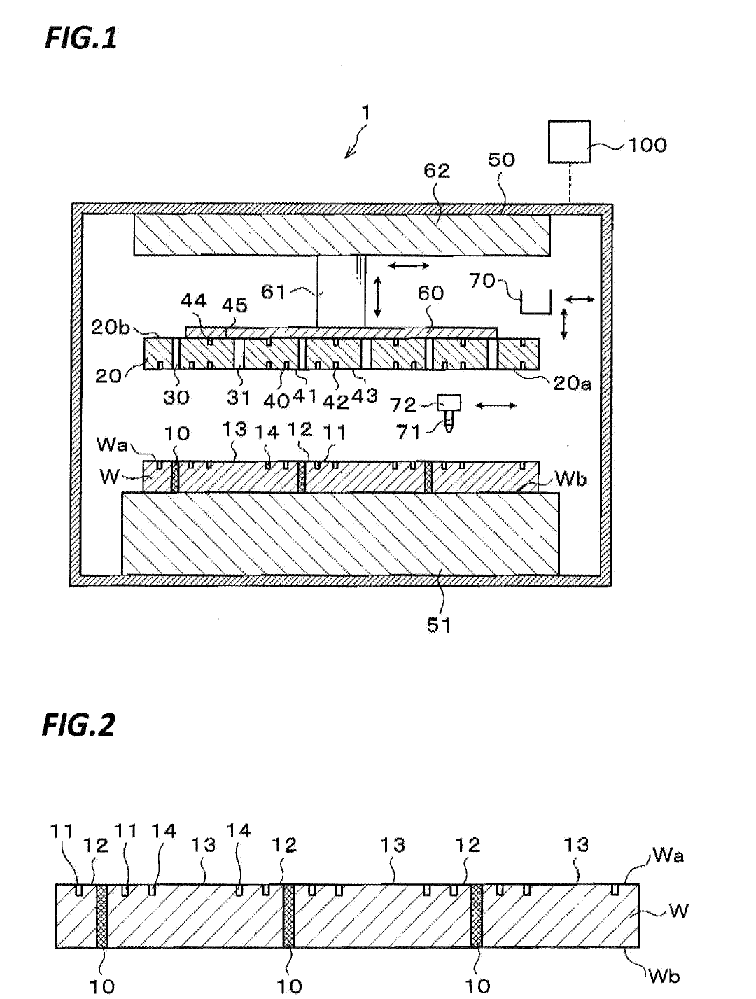

FIG. 1 is a longitudinal cross-sectional view illustrating a schematic configuration of a wafer processing apparatus 1 for performing a processing method of a wafer as a substrate, according to the present exemplary embodiment. Further, in the present exemplary embodiment, a wafer processing will be described with respect to a processing in which a plating liquid serving as a processing liquid is supplied to through silicon vias (TSVs in the 3D integration technique) formed on a wafer and a plating processing is performed to form, for example, bumps.

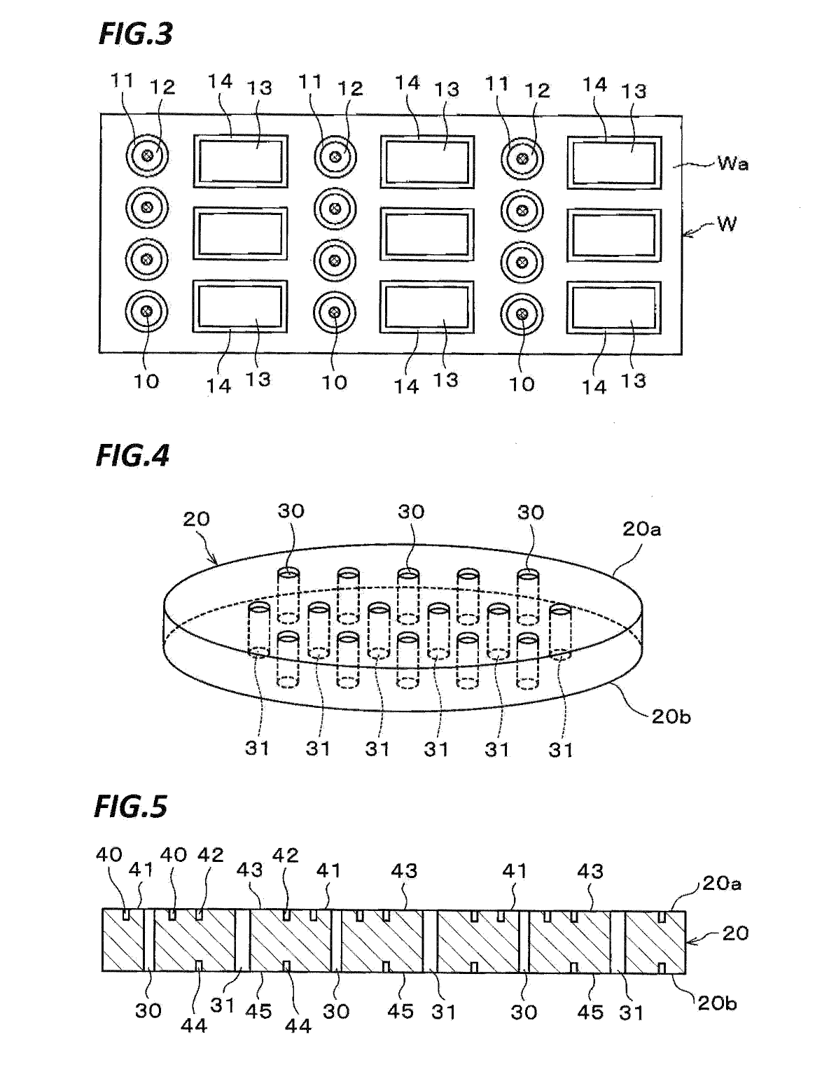

A wafer W processed in the wafer processing apparatus 1 of the present exemplary embodiment is formed with a plurality of through silicon vias 10 that penetrate from a front surface Wa to a rear surface Wb in a thickness direction as illustrated in FIG. 2. The plurality of through silicon vias 10 is formed to be aligned to positions on the front surface Wa of the wafer W as illustrated in FIG. 3. A plurality of via groups including a plurality of the aligned through silicon vias 10 is formed on the front surface Wa of the wafer W, for example, in a semiconductor chip unit. Further, FIG. 3 is a view drawing a part of the front surface Wa of the wafer W. The wafer W has a substantially circular shape when viewed from the top.

As illustrated in FIGS. 2 and 3, on the front surface Wa of the wafer W, an annular groove 11 is formed around each of the through silicon vias 10. A processing region 12 is formed in an inner region of the groove 11, in which a plating liquid is supplied to the processing region 12 such that a plating processing is performed therein as described below.

Here, the plating liquid supplied to the processing region 12 is diffused with a certain contact angle with a larger contact angle at a peripheral edge of the groove 11. Then, the plating liquid remains in the processing region 12 without running over the groove 11. A phenomenon that a groove 11 suppresses diffusion of the plating liquid is known as so-called a pinning effect. Accordingly, the processing region 12 has a surface of the same quality as the front surface Wa outside the processing region 12. However, due to the pinning effect of the groove 11, the processing region 12 functions as a hydrophilic region having hydrophilicity as compared to the region outside the processing region 12 in appearance.

Further, on the front surface Wa of the wafer W, a plurality of alignment regions 13 are formed at positions which are different from those of the processing regions 12. The alignment regions 13 are provided so as to perform alignment of a template 20 and the wafer W by supplying deionized water as an alignment liquid as described below. The alignment regions 13 are formed on, for example, scribe lines. The scribe lines refer to lines which allow the wafer W to be cut and divided into a plurality of semiconductor chips. A device layer (not illustrated) including an electronic circuit connected to the through silicon vias 10, or a signal wiring for power, ground or address is formed on the front surface Wa of the wafer W, but an electronic circuit or wiring is not formed on or around the scribe lines. Accordingly, even if deionized water is supplied to the alignment regions 13, the semiconductor chips are not adversely affected.

Similarly to the processing region 12, each alignment region 13 is formed in an inner region of an annular groove 14. Accordingly, the alignment region 13 also functions as a hydrophilic region having hydrophilicity as compared to the region outside the alignment region 13 in appearance, due to the pinning effect of the groove 14.

Further, in the wafer W, the grooves 11, 14 are respectively formed with high positional accuracy by, for example, machining or performing a photolithography processing and an etching in batches. Therefore, any special processes are not needed in forming the grooves 11, 14.

Further, a template 20 having a substantially disc shape as illustrated in FIGS. 4 to 7 is used in the wafer processing apparatus 1 of the present exemplary embodiment. The template 20 is made of, for example, silicon (Si) or silicon carbide (SiC).

The template 20 is formed with a plurality of plating passages 30 serving as processing liquid passages, which penetrates from a front surface 20a to a rear surface 20b of the template 20 in a thickness direction thereof and passes the plating liquid, as illustrated in FIGS. 4 and 5. Each of the plating liquid passages 30 is formed at a position corresponding to one of the through silicon vias 10 formed in the wafer W. Further, the template 20 is formed with a plurality of deionized water passages 31 serving as alignment liquid passages, which penetrate from the front surface 20a to the rear surface 20b of the template 20 in the thickness direction thereof and passes deionized water. Each of the deionized water passages 31 is formed at a position corresponding to one of the processing regions 12 formed on the wafer W, that is, the positions where the deionized water is able to be supplied to the processing regions 12.

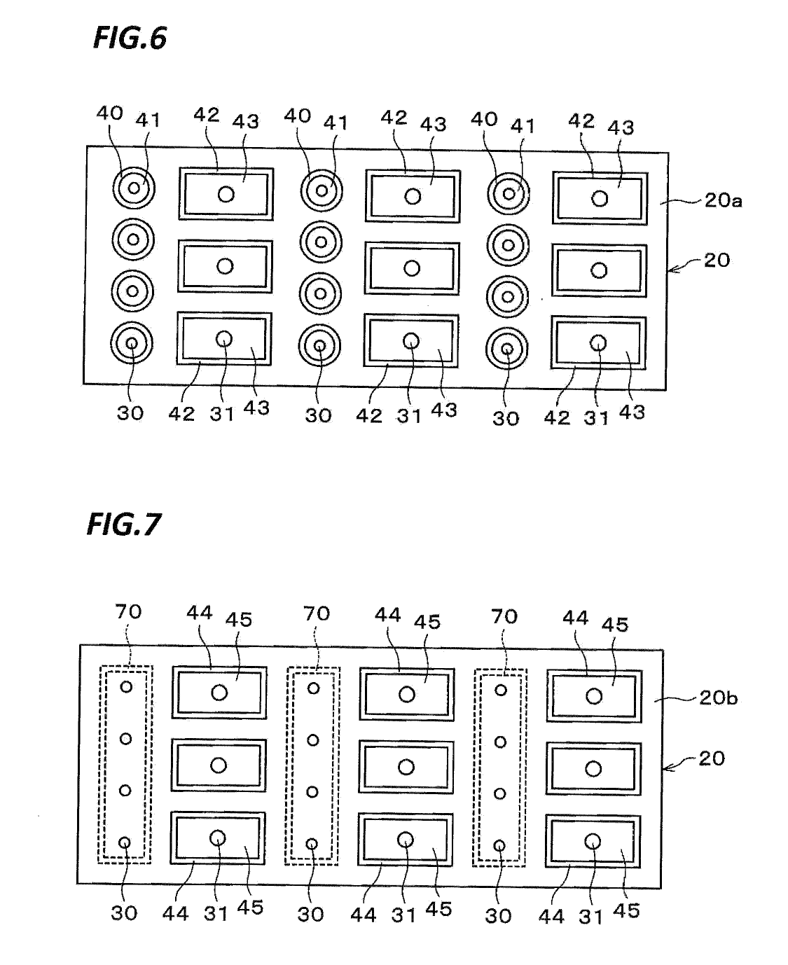

As illustrated in FIG. 6, each annular groove 40 is formed around one of the plating liquid passages 30 on the front surface 20a of the template 20. A first hydrophilic region 41 is formed in the inner region of each groove 40. Each first hydrophilic region 41 is formed at a position corresponding to one of the processing region 12. Further, the first hydrophilic region 41 functions as a hydrophilic region having hydrophilicity as compared to the region outside the first hydrophilic region 41 in appearance, due to the pinning effect of the groove 40.

Further, on the front surface 20a of the template 20, an annular groove 42 is formed around each of the deionized water passages 31. In an inner region of the groove 40, a second hydrophilic region 43 is formed. Each second hydrophilic region 43 is formed at a position corresponding to one the alignment regions 13. Further, the second hydrophilic region 43 functions as a hydrophilic region having hydrophilicity as compared to the region outside the second hydrophilic region 43 in appearance, due to the pinning effect of the groove 42.

Further, as illustrated in FIG. 7, on the rear surface 20b of the template 20, an annular groove 44 is formed around each of the deionized water passages 31. In an inner region of the groove 44, a third hydrophilic region 45 is formed. The third hydrophilic region 45 is formed such that the deionized water on the rear surface 20b is not diffused to a region outside the third hydrophilic region 45. And, the third hydrophilic region 45 functions as a hydrophilic region having hydrophilicity as compared to the region outside the third hydrophilic region 45 in appearance, due to the pinning effect of the groove 44. Specifically, since the third hydrophilic region 45 is positioned on the rear surface 20b of the template 20 which is not formed with the device layer, a range of adjusting the area of the region is wide. Further, if the deionized water does not flow out on the rear surface 20b when the alignment of the template 20 and the wafer W is performed as described below, the third hydrophilic region 45 may not be provided.

Further, in the template 20, the plating liquid passages 30, the deionized water passages 31, and grooves 40, 42, 44 are formed with high positional accuracy by, for example, machining or performing a photolithography processing and an etching in batches.

As illustrated in FIG. 1, the wafer processing apparatus 1 of the present exemplary embodiment is provided with a processing chamber 50 configured to accommodate a wafer W therein. A placing table 51 on which the wafer W is placed is provided on the bottom of the processing chamber 50. For example, a vacuum chuck is used in the placing table 51, and the wafer W is placed horizontally on the placing table 51 in a state where the front surface Wa of the wafer W faces upwardly.

A holding member 60 configured to hold the template 20 is disposed above the placing table 51. The holding member 60 holds the template 20 in a state where the front surface 20a of the template 20 faces downwardly. And, the template 20 held by the holding member 60 is disposed such that the front surface 20a faces the front surface Wa of the wafer W on the placing table 51.

The holding member 60 is supported through a shaft 61 to a moving mechanism 62 provided on a ceiling in the processing chamber 50. The template 20 and the holding member 60 are configured to be movable vertically and horizontally by the moving mechanism 62.

Inside the processing chamber 50 and above the template 20, a plating liquid supply unit 70 configured to supply the plating liquid from the rear surface 20b of the template 20 to the plating liquid passages 30 is provided. The plating liquid supply unit 70 is configured to be movable vertically and horizontally by a moving mechanism (not illustrated). Further, various means may be used for the plating liquid supply unit 70. However, a pod configured to temporarily store and supply the plating liquid is used in the present exemplary embodiment.

Further, inside the processing chamber 50 and between the template 20 and the wafer W, a deionized water supply unit 71 configured to supply deionized water to the wafer W is provided. The deionized water supply unit 71 is configured to be movable vertically and horizontally by a moving mechanism 72. Further, various means may be used for the deionized water supply unit 71. However, a nozzle configured to eject the deionized water is used in the present exemplary embodiment.

The wafer processing apparatus 1 is provided with a control unit 100. The control unit 100 is, for example, a computer, and includes a program storage unit (not illustrated). The program storage unit stores a program that executes a wafer processing in the wafer processing apparatus 1 as described below. Further, the program may be recorded in a recording medium readable by a computer, such as, for example, a hard disc (HD), a flexible disc (FD), a compact disc (CD), a magnet optical disc (MO), or a computer-readable memory card, or installed from the recording medium to the control unit 100.

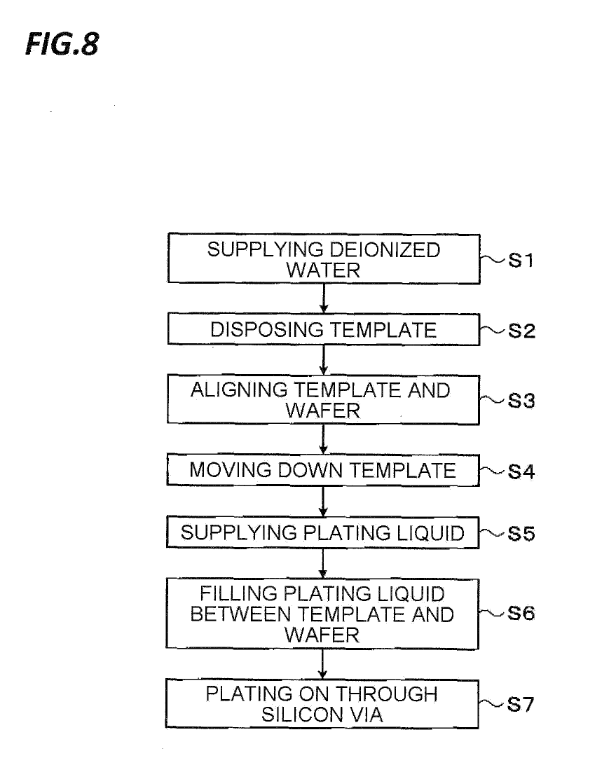

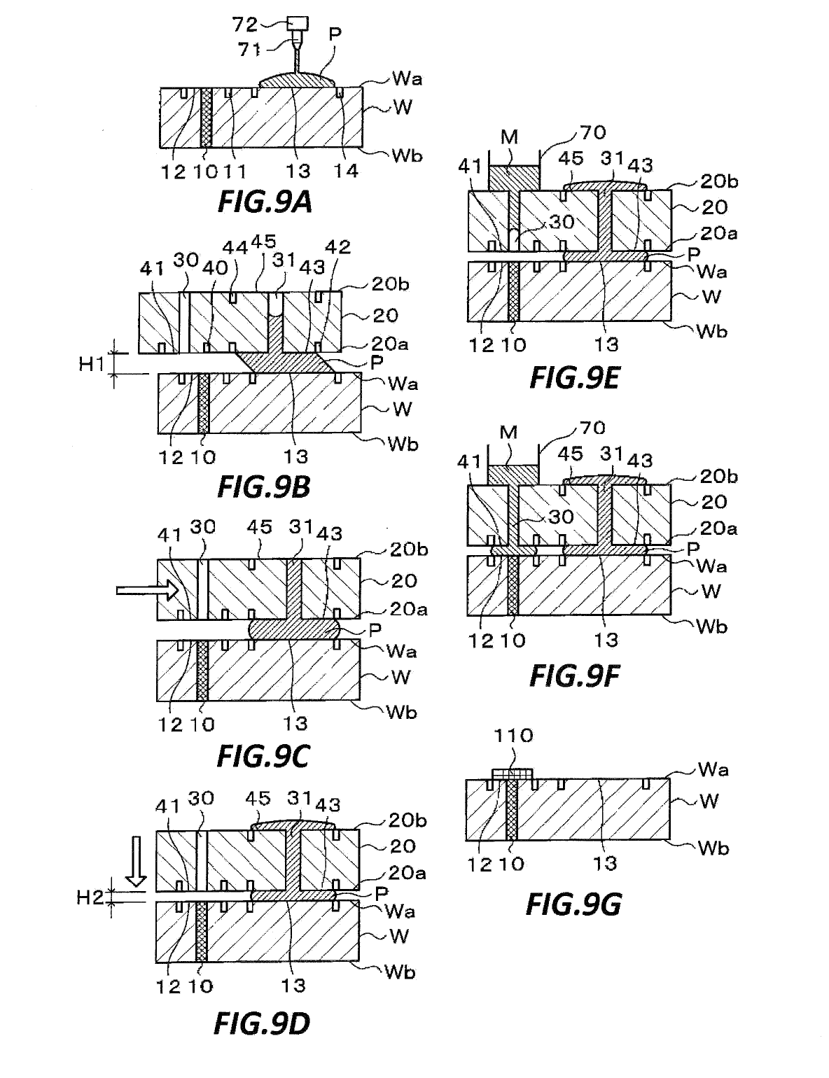

Next, descriptions will be made on a processing of the wafer W performed using the wafer processing apparatus 1 as configured above. FIG. 8 is a flowchart illustrating main steps of the wafer processing. FIGS. 9A to 9G are explanatory views schematically illustrating a state of the template 20 and the wafer W in each wafer processing step. Further, in order to prioritize ease of understanding of the technology, FIGS. 9A to 9G illustrate a part of the wafer W (in the vicinity of one processing region 12 and one alignment region 13) and a part of the template 20 (in the vicinity of one first hydrophilic region 41 and one second hydrophilic region 43).

First, in the wafer processing apparatus 1, the template 20 is held in the holding member 60, and the wafer W is placed on the placing table 51 at the same time. The template 20 is held in the holding member 60 such that the front surface 20a faces downwardly. Further, the wafer W is placed on the placing table 51 such that the front surface Wa faces upwardly.

Then, as illustrated in FIG. 9A, the deionized water supply unit 71 is disposed above the alignment region 13 of the wafer W by the moving mechanism 72. And, a predetermined amount of deionized water P is supplied to the alignment region 13 from the deionized water supply unit 71 (step S1 in FIG. 8). Further, for one wafer W, the deionized water P of, for example, 13 ml is supplied.

When a predetermined amount of the deionized water is supplied to the alignment region 13, the moving mechanism 62 aligns the template 20 horizontally and moves the template 20 down to a predetermined position at the same time. Further, the alignment of the template 20 by the moving mechanism 62 is performed by, for example, an optical sensor (not illustrated). Then, as illustrated in FIG. 9B, the template 20 is disposed above the wafer W (step S2 in FIG. 8). At this time, the template 20 is disposed such that the position of the first hydrophilic region 41 corresponds to the position of the processing region 12, and the position of the second hydrophilic region 43 corresponds to the position of the alignment region 13. Further, the positions of the first hydrophilic region 41 and the processing region 12, and the positions of the second hydrophilic region 43 and the alignment region 13 do not necessarily correspond strictly to each other. Even if these positions are somewhat dislocated, the alignment of the template 20 and the wafer W is performed in step S3 to be described later.

In step S2, a vertical distance H1 between the template 20 and the wafer W is, for example, 50 μm to 200 μm, and 100 μm in the present exemplary embodiment. When the distance H1 is maintained at such a distance, the template 20 is movable relatively horizontally with respect to the wafer W. Further, the distance H1 is a distance at which the template 20 is moved as described below and the alignment of the template 20 and the wafer W is performed. Here, a restoring force acts on the template 20 by surface tension of the deionized water P filled between the second hydrophilic region 43 and the alignment region 13 as described below, thereby performing the alignment of the template 20 and the wafer W. The distance H1 is set so as to secure the restoring force, that is, the surface tension of the deionized water P. Specifically, the distance H1 may be adjusted by, for example, the supplied amount of the deionized water P, each area of the alignment region 13 and the second hydrophilic region 43, and the weight of the template 20 itself. In addition, as the distance H1 decreases, the restoring force acting on the template 20 increases. However, in a case where the distance H1 is too small, the template 20 and the wafer W might come into contact with each other when at least one of the template 20 and the wafer W is inclined. Therefore, the lower limit of the distance H1 is preferably 50 μm.

In addition, in step S2, the deionized water P on the alignment region 13 is diffused to the end of the alignment region 13 horizontally by a capillary phenomenon and climbs along the deionized water passage 31 of the template 20 vertically at the same time. Further, the deionized water P is diffused between the second hydrophilic region 43 and the alignment region 13, but due to the pinning effect of the grooves 42, 14, the deionized water P is not diffused to a region outside the second hydrophilic region 43 and the alignment region 13.

Thereafter, the restoring force (indicated by an arrow in FIG. 9C) moving the template 20 as illustrated in FIG. 9C is applied to the template 20 by the surface tension of the deionized water P filled between the second hydrophilic region 43 and the alignment region 13. Then, even if the positions of the first hydrophilic region 41 and the processing region 12, and the positions of the second hydrophilic region 43 and the alignment region 13 are dislocated, the template 20 is moved such that these regions face each other, thereby performing the alignment of the template 20 and the wafer W (step S3 in FIG. 8). Then, the plating liquid passage 30 is disposed above the through silicon via 10. For the convenience of description, step S2 and step S3 are described sequentially. However, the steps proceed almost simultaneously in practice.

Then, as illustrated in FIG. 9D, the template 20 is moved down by, for example, the moving mechanism 62 (step S4 in FIG. 8). At this time, a vertical distance H2 between the template 20 and the wafer W is, for example, 5 μm. The distance H2 is determined by a thickness of a bump formed on the through silicon via 10 as described below. Meanwhile, the smaller the distance H2 is, the more the time for performing a plating processing to form a bump is shortened. Therefore, the distance between the template 20 and the wafer W is set to be small by moving down the template 20. Then, the distance H2 between the template 20 and the wafer W is measured by a laser displacement meter (not illustrated), and when the distance H2 reaches 5 μm, the downward movement of the template 20 is stopped. Further, when the template 20 is moved down, for example, a separate load mechanism (not illustrate) configured to apply a load on the template 20 may be used instead of the moving mechanism 62. When the template 20 has sufficient own weight, the template 20 is moved down by the own weight. Alternatively, the downward movement of the template 20 may be controlled by a pressure of the deionized water P that flows out on the rear surface 20b of the template 20 as described below.

Further, in step S4, the deionized water P in the deionized water passage 31 flows out on the rear surface 20b of the template 20. The deionized water P which flows out is diffused in the third hydrophilic region 45. Further, due to the pinning effect of the groove 44, the deionized water P is not diffused to a region outside the third hydrophilic region 45. In other words, the range of the third hydrophilic region 45 is determined such that an optimal amount of the deionized water P flows out of the deionized water passage 31.

Then, as illustrated in FIG. 9E, the plating liquid supply unit 70 is disposed on the plating liquid passage 30 on the rear surface 20b of the template 20. The plating liquid supply unit 70 is supplied with a plating liquid M from a plating liquid source (not illustrated). Then, the plating liquid M is supplied from the plating liquid supply unit 70 to the plating liquid passage 30 (step S5 in FIG. 8). Then, since the plating liquid passage 30 has a fine diameter, the supplied plating liquid M is passed in the plating liquid passage 30 due to a capillary phenomenon. Further, various plating liquids may be used as the plating liquid M. In the present exemplary embodiment, descriptions will be made on a case where a plating liquid M containing, for example, CuSO₄ pentahydrate and sulfuric acid is used. However, for example, a plating liquid containing silver nitrate, ammonia water and glucose, or an electroless copper plating liquid may be used for the plating liquid M.

When the plating liquid M is passed to the end of the plating liquid passage 30, the plating liquid M is further diffused horizontally due to the capillary phenomenon, as illustrated in FIG. 9F. That is, the plating liquid M enters a space between the first hydrophilic region 41 of the template 20 and the processing region 12 of the wafer W. Therefore, the plating liquid M is filled between the first hydrophilic region 41 and the processing region 12 (step S6 in FIG. 8). Further, the deionized water P is diffused between the first hydrophilic region 41 and the processing region 12. However, due to the pinning effect of the grooves 40, 11, the plating liquid M is not diffused to a region outside the first hydrophilic region 41 and the processing region 12.

Thereafter, a voltage is applied to the plating liquid M between the first hydrophilic region 41 and the processing region 12 by a power supply unit (not illustrated). Then, the plating liquid M reacts and the plating processing is performed on the through silicon via 10 (step S7 in FIG. 8). And, as illustrated in FIG. 9G, a bump 110 is formed on the through silicon via 10.

According to the exemplary embodiment as described above, before the plate liquid M is supplied to the processing region 12 of the wafer W in steps S5 and S6, the alignment of the template 20 with respect to the wafer W is performed by the deionized water P supplied between the second hydrophilic region 43 of the template 20 and the alignment region 13 of the wafer W in steps S1 to S3. That is, a restoring force acts on the template 20 by surface tension of the deionized water P filled between the second hydrophilic region 43 and the alignment region 13, thereby moving the template 20 such that the plating liquid passage 30 is positioned above the through silicon via 10. Therefore, the alignment of the template 20 and the wafer W may be performed with high accuracy, and thus, in the subsequent steps S5 and S6, the plating liquid M may be supplied properly to the processing region 12 of the wafer W with high positional accuracy. Thus, according to the present exemplary embodiment, the plating liquid M may be supplied to a predetermined position of the wafer W with high positional accuracy, and the plating processing may be performed properly on the through silicon via 10 of the wafer W by using the plating liquid M.

Here, the inventors have tried to use the plating liquid M supplied from the plating liquid passage 30 of the template 20 without using the deionized water P as in the present disclosure when performing the alignment of the template 20 and the wafer W. That is, the inventors have tried to make the processing region 12 function as an alignment region, and use the plating liquid M as an alignment liquid.

In this case, since the diameter of the through silicon via 10 is very small and the processing region 12 surrounding the through silicon via is a small region, it is difficult to secure sufficient surface tension of the plating liquid M on the processing region 12. Therefore, the restoring force acting on the template 20 becomes smaller, and thus, the template 20 is not moved to a proper position. Accordingly, the alignment of the template 20 and the wafer W may not be performed properly. Further, in a case where the alignment of the template 20 and the wafer W is performed using the plating liquid M, at least, it is necessary that the plating liquid passage 30 and the through silicon via 10 are overlapped to some extent when supplying the plating liquid M to the wafer W. However, when the through silicon via 10 of the wafer W is miniaturized as the miniaturization of semiconductor devices proceeds, it becomes difficult to overlap the plating liquid passage 30 and the through silicon via 10.

In this regard, in the present exemplary embodiment, since the alignment of the template 20 and the wafer W is performed using the deionized water P supplied to the alignment region 13 having a large area, it is possible to secure sufficient surface tension of the deionized water P. Accordingly, it is possible to increase the restoring force acting on the template 20, and thus, it is possible to properly perform the alignment of the template 20 and the wafer W. Further, since the alignment is performed using the deionized water P that is a separate component from the plating liquid M, it is possible to properly perform the alignment of the template 20 and the wafer W even in a case where the position of the plating liquid passage 30 of the template 20 does not correspond to the position of the processing region 12 due to the small diameter of the through silicon via 10 and the small area of the processing region 12.

Further, since the deionized water P has large surface tension, a large restoring force may act on the template 20. Therefore, it is possible to more properly perform the alignment of the template 20 and the wafer W. Furthermore, in a case of using the deionized water P, it is not necessary to clean the deionized water P between the template 20 and the wafer W later, and thus, it is also possible to enhance the throughput of the wafer processing.

Further, in step S3, since the distance H1 between the template 20 and the wafer W is 100 μm, it is possible to perform the alignment of the template 20 and the wafer W without contacting the template 20 and the wafer W. Then, in step S4, the template 20 is moved down such that the distance H2 between the template 20 and the wafer W is set to 5 μm. Therefore, it is possible to perform the plating processing in a short time even when the bump 110 is formed on the through silicon via 10 using the plating liquid M. Accordingly, it is possible to further enhance the throughput of the wafer processing.

The processing region 12 and the alignment region 13 of the wafer W, and the first hydrophilic region 41, the second hydrophilic region 43 and the third hydrophilic region 45 of the template 20 have hydrophilicity in appearance, respectively. That is, in these regions 12, 13, 41, 43, 45, the plating liquid M or the deionized water P is not diffused to a region outside the regions 12, 13, 41, 43, 45 due to the pinning effect of the grooves 11, 14, 40, 42, 44, respectively. Accordingly, the plating liquid M or the deionized water P is not diffused to any region other than a desired region, and thus, it is possible to properly perform the alignment of the template 20 and the wafer W and properly perform the plating processing on the through silicon via of the wafer W.

In the exemplary embodiment as described above, the processing region 12, the alignment region 13, the first hydrophilic region 41, the second hydrophilic region 43, and the third hydrophilic region 45 have hydrophilic regions formed by the grooves 11, 14, 40, 42, 44, respectively. However, the hydrophilic region may be formed in other manners.

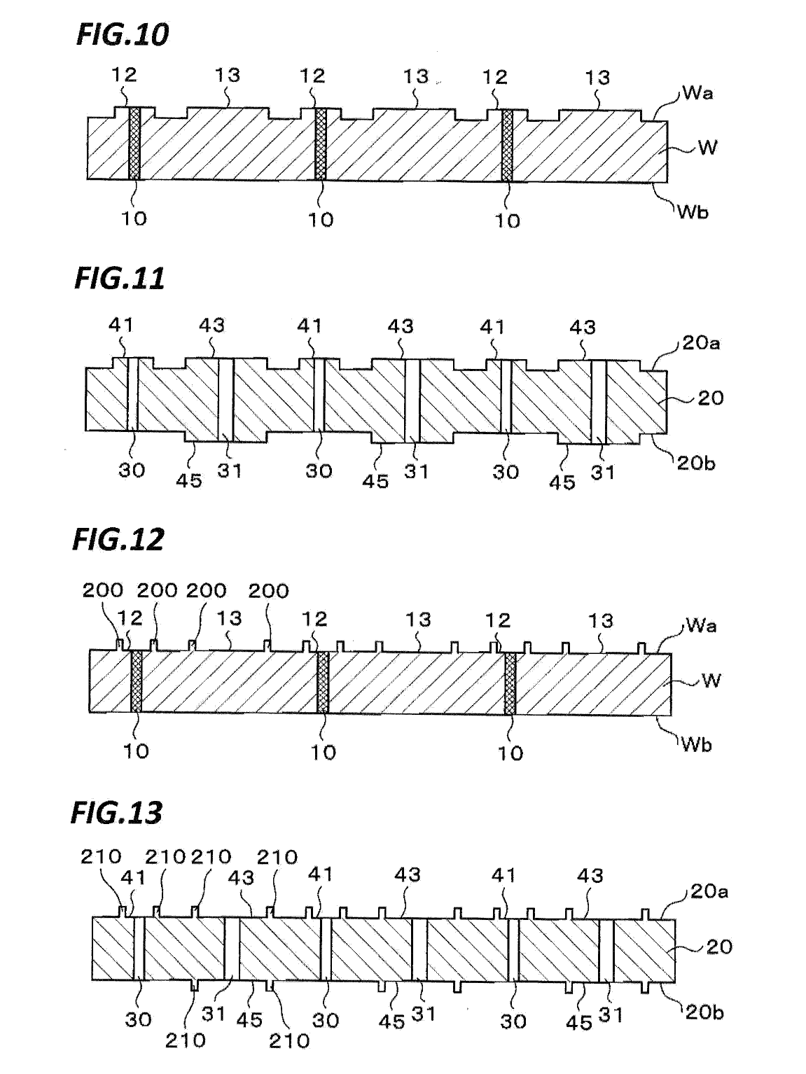

For example, in order to form a hydrophilic region by a pinning effect, a step may be formed in and around the hydrophilic region, and a step structure is not limited to formation of grooves. For example, as illustrated in FIG. 10, the processing regions 12 and the alignment regions 13 on the wafer W may protrude as compared to surrounding regions thereof. In this case, the diffusion of the plating liquid M and the deionized water P supplied to the processing regions 12 and the alignment regions 13, respectively, is stopped at the shoulder portions of the processing regions 12 and the alignment regions 13 by the pinning effect. Accordingly, the processing regions 12 and the alignment regions 13 may be made as hydrophilic regions in appearance.

For the template 20, as illustrated in FIG. 11, the first hydrophilic regions 41, the second hydrophilic regions 43, and the third hydrophilic regions 45 may protrude as compared to surrounding regions thereof. In this case, the diffusion of the plating liquid M and the deionized water P supplied to the first hydrophilic regions 41, the second hydrophilic regions 43, and the third hydrophilic regions 45, respectively, is stopped at the shoulder portions of the first hydrophilic regions 41, the second hydrophilic regions 43, and the third hydrophilic regions 45 by the pinning effect. Accordingly, the first hydrophilic regions 41, the second hydrophilic regions 43, and the third hydrophilic regions 45 may be made as hydrophilic regions in appearance.

Further, for example, as illustrated in FIG. 12, protrusions 200 may be formed around the processing regions 12 (through silicon vias 10) and around the alignment regions 13, respectively, on the wafer W. In this case, the diffusion of the plating liquid M and the deionized water P supplied to the processing regions 12 and the alignment regions 13, respectively, is stopped at the shoulder portions of the protrusions 200 by the pinning effect. Accordingly, the processing regions 12 and the alignment regions 13 may be made as hydrophilic regions in appearance.

For the template 20, as illustrated in FIG. 13, protrusions 210 may be formed around the first hydrophilic regions 12 (plating liquid passages 30) and around the second hydrophilic regions 43 and the third hydrophilic regions 45 (deionized water passages 31), respectively. In this case, the diffusion of the plating liquid M and the deionized water P supplied to the first hydrophilic regions 41, the second hydrophilic regions 43, and the third hydrophilic regions 45, respectively, is stopped at the shoulder portions of the first hydrophilic regions 41, the second hydrophilic regions 43, and the third hydrophilic regions 45 by the pinning effect. Accordingly, the first hydrophilic regions 41, the second hydrophilic regions 43, and the third hydrophilic regions 45 may be made as hydrophilic regions in appearance.

As described above, the method of forming the processing regions 12, the alignment regions 13, the first hydrophilic regions 41, the second hydrophilic regions 43, and the third hydrophilic regions 45 to protrude, or forming the protrusions 200, 210, is particularly useful in a case where an important film is formed on the front surface Wa of the wafer W, and thus, grooves 11, 14, 40, 42, 44 cannot be formed with sufficient depth. Further, these regions formed to protrude or the protrusions 200, 210 may be obtained by patterning a film, which is formed by CVD, with a lithography technology.

Further, in a case of forming the grooves 11, 14, 40, 42, 44 or protrusions 200, 210, or forming the processing regions 12, the alignment regions 13, the first hydrophilic regions 41, the second hydrophilic regions 43, and the third hydrophilic regions 45 to protrude in order to obtain the pinning effect, the front surface Wa of the wafer W or the front surface 20a and the rear surface 20b of the template 20 may be subjected to a combination of a hydrophilic treatment and a hydrophobic treatment, which will be described later, as necessary. It is possible to define spreading of a liquid surface more securely by the combination.

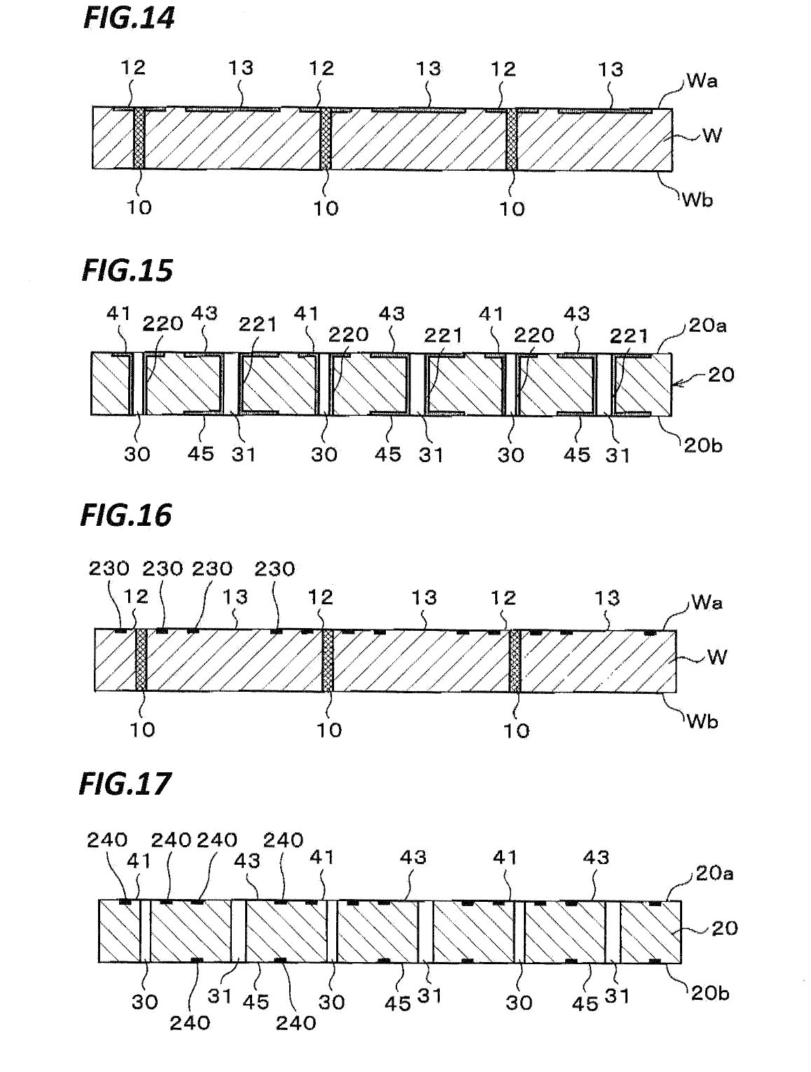

The hydrophilic regions may be formed, for example, by modifying the front surface Wa of the wafer W and the front surface 20a and the rear surface 20b of the template 20. For example, as illustrated in FIG. 14, in the front surface Wa of the wafer W, the processing regions 12 and the alignment regions 13 have hydrophilicity as compared to other regions. When forming the processing regions 12 and the alignment regions 13, the front surface Wa may be subjected to a hydrophilic treatment in predetermined regions and subjected to a hydrophobic treatment in the other regions. Alternatively, the front surface Wa may be subjected to a hydrophilic treatment and a hydrophobic treatment at the same time.

For the template 20, as illustrated in FIG. 15, in the front surface 20a of the template 20, the first hydrophilic regions 41 and the second hydrophilic regions 43 have hydrophilicity as compared to other regions, and in the rear surface 20b, the third hydrophilic regions 45 have hydrophilicity as compared to the other regions. When forming the first hydrophilic regions 41, the second hydrophilic regions 43, and the hydrophilic regions 45, the front surface 20a and the rear surface 20b may be subjected to a hydrophilic treatment in predetermined regions and subjected to a hydrophobic treatment in the other regions. Alternatively, the front surface 20a and the rear surface 20b may be subjected to a hydrophilic treatment and a hydrophobic treatment at the same time.

Further, in the template 20, fourth hydrophilic regions 220 and fifth hydrophilic regions 221 are formed on the inner surfaces of the plating liquid passages 30 and the deionized water passages 31. When forming the fourth hydrophilic regions 220 and the fifth hydrophilic regions 221, the plating liquid passages 30 and the deionized water passages 31 are subjected to a hydrophilic treatment, respectively. When the inner surfaces of the plating liquid passages 30 and the deionized water passages 31 are subjected to a hydrophilic treatment, the plating liquid M and the deionized water P may be passed more smoothly.

Further, for example, as illustrated in FIG. 16, annular hydrophobic regions 230 may be formed around the processing regions 12 and the alignment regions 13 of the wafer W, respectively. Similarly, as illustrated in FIG. 17, annular hydrophobic regions 240 may be formed around the first hydrophilic regions 41, the second hydrophilic regions 43, and the third hydrophilic regions 45, respectively. In this case, the liquid surfaces of the plating liquid M and the deionized water P supplied to inner regions of the hydrophobic regions 230, 240 spread respectively with the hydrophobic regions 230, 240 as borders. Accordingly, it is possible to form the processing regions 12, the alignment regions 13, the first hydrophilic regions 41, the second hydrophilic regions 43, and the third hydrophilic regions 45 as hydrophilic regions in appearance. The hydrophobic regions 230, 240 need not to have wide areas as long as the hydrophobic regions 230, 240 surround desired hydrophilic regions 41, 43, 45. Accordingly, the processing regions may be reduced on the front surface Wa of the wafer W, and the front surface 20a and the rear surface 20b of the template 20.

As described above, in all the cases of FIGS. 10 to 17, since the processing regions 12, the alignment regions 13, the first hydrophilic regions 41, the second hydrophilic regions 43, and the third hydrophilic regions 45 may be formed as hydrophilic regions, the plating liquid M or the deionized water P are not diffused to the regions other than the desired regions. Accordingly, the alignment of the template 20 and the wafer W may be properly performed, and the plating processing may be properly performed on the through silicon vias 10 of the wafer W.

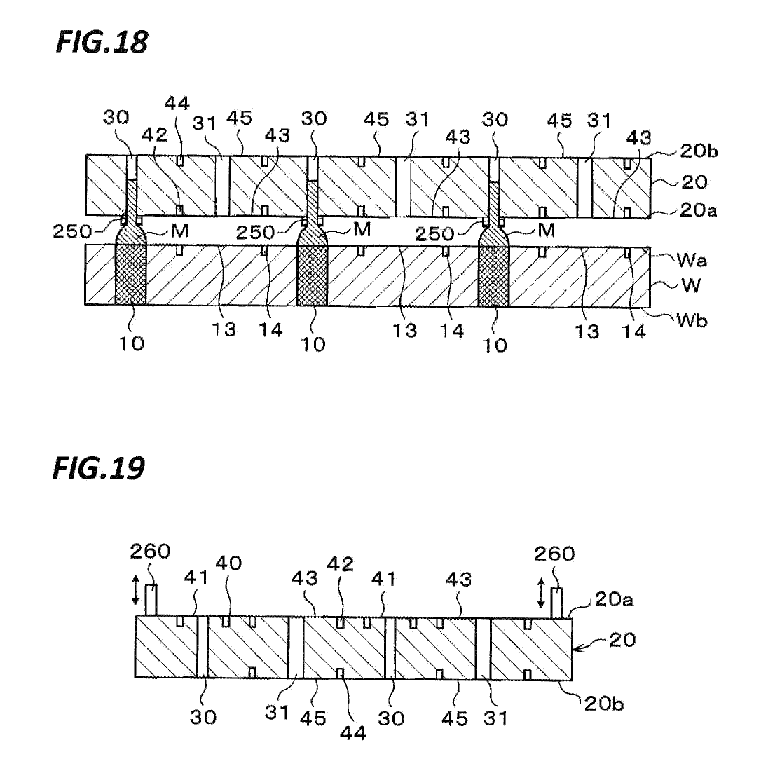

In the exemplary embodiments as described above, the processing regions 12 of the wafer W and the first hydrophilic regions 41 of the template 20 are formed as hydrophilic regions. However, instead of these hydrophilic regions, protrusions 250 may be formed as other protrusions on the front surface 20a of the template 20, as illustrated in FIG. 18. The protrusions 250 are formed at the positions corresponding to the plating liquid passages 30. That is, the plating liquid passages 30 penetrate through the protrusions 250 and protrude above the surrounding front surface 20a. Further, the protrusions 250 may be formed by embedding pipes opened at both ends inside the template 20 or t by polishing the surrounding regions the protrusions 250. Further, similarly to the exemplary embodiments as described above, each of the wafer W and the template 20 is formed with alignment regions 13, second hydrophilic regions 43, and third hydrophilic regions 45.

In this case, in step S5, when the plating liquid M is supplied to the plating liquid passages 30, the plating liquid M is passed in the plating liquid passages 30 by the capillary phenomenon to enter between the template 20 and the wafer W. At this time, the plating liquid M flowing out of the plating liquid passages 30 is suppressed from being diffused horizontally by the pinning effect of the protrusions 250, and is supplied to the wafer W. Accordingly, the plating liquid M is supplied only to the through silicon vias 10 with high positional accuracy. Since the other steps S1 to S4 and S7 are similar to steps S1 to S4 and S7 in the exemplary embodiments as described above, descriptions thereof will be omitted.

As described above, according to the present exemplary embodiment, the plating liquid M may be supplied properly to the through silicon vias 10 without forming the processing regions 12 and the first hydrophilic regions 41. Accordingly, it the plating processing may be properly performed in the subsequent step S7. In a case where circuits are densely formed on the front surface Wa of the wafer W and the processing regions 12 may not be formed on the front surface Wa, the present exemplary embodiment is particularly useful. Further, in the present exemplary embodiment, the protrusions 250 are formed at the positions corresponding to the plating liquid passages 30 of the template 20. However, the protrusions may be formed at the positions corresponding to the deionized water passages 31. In this case, the alignment of the template 20 and the wafer W is performed by the deionized water supplied from the protrusions of the template 20.

The template 20 in the exemplary embodiments as described above may be provided with elevation mechanisms 260 configured to align relative positions of the template 20 and the wafer W as illustrated in FIG. 19. A plurality of elevation mechanisms 260 is provided in the outer peripheral portion on the front surface 20a of the template 20. Further, for example, extensible elevation pins are used in the elevation mechanisms 260.

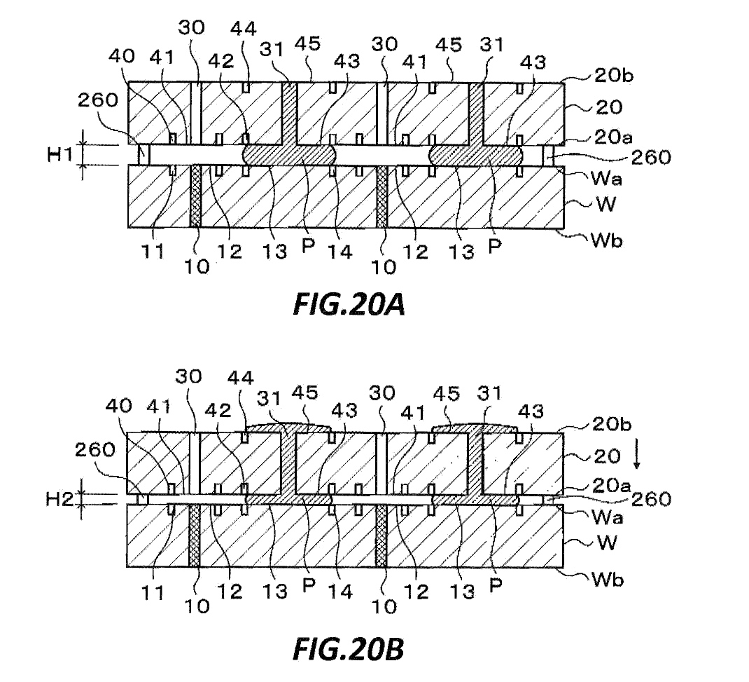

In this case, when the template 20 is disposed above the wafer W in step S2, the template 20 and the wafer W are supported by the elevation mechanisms 260 therebetween as illustrated in FIG. 20A. Then, a distance H1 between the template 20 and the wafer W is maintained to an appropriate distance, for example, 50 μm to 200 μm by the elevation mechanisms 260. In this step, since the template 20 is supported by the elevation mechanisms 260, the template 20 may maintain its horizontal state more precisely as compared to a case where the elevation mechanisms 260 are not provided. Next, reduction of the elevation mechanisms 260 is started. When the reduction of the elevation mechanisms 260 is started, the template is supported only by the deionized water P, and the alignment of the template 20 and the wafer W of step 3 proceeds. At the same time, the template 20 is moved down by its own weight, and the deionized water P passes through the deionized water passages 31 and is diffused to the third hydrophilic regions 43. When the height of the template elevation mechanisms 260 reaches H2, the template 20 is supported again by the elevation mechanisms 260. The distance H2 between the template 20 and the wafer W may be maintained to an appropriate distance, for example, 5 μm. Since other steps S1 to S4 and S7 are similar to steps S1 to S4 and S7 in the exemplary embodiments as described above, descriptions thereof will be omitted.

According to the present exemplary embodiment, since the distances H1, H2 between the template 20 and the wafer W are controlled to appropriate distances, respectively, by the elevation mechanisms 260, the alignment of the template 20 and the wafer W and the plating processing may be properly performed. When the distances H1, H2 are very small and the weight of the template 20 is large, the distances H1, H2 may not be maintained properly only by the plating liquid M and the deionized water P. In such a case, the present exemplary embodiment is particularly useful because the distances H1, H2 may be maintained physically by the elevation mechanisms 260.

In the exemplary embodiments as described above, the deionized water P is supplied to the alignment regions 13 of the wafer W in step S1 before the template 20 is disposed above the wafer W in step S2. However, the deionized water P may be supplied to the alignment regions 13 after the template 20 is disposed above the wafer W.

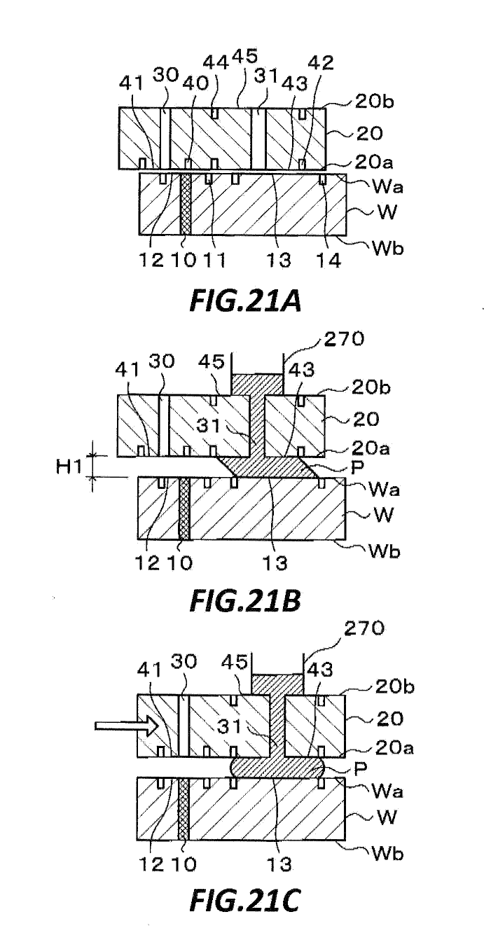

In this case, as illustrated in FIG. 21A, the template 20 is disposed on the wafer W such that the front surface 20a of the template 20 and the front surface Wa of the wafer W are overlapped with each other.

Then, as illustrated in FIG. 21B, a deionized water supply unit 270 configured to temporarily store and supply deionized water P is disposed on a deionized water passage 31 on the rear surface 20b of the template 20. The deionized water supply unit 270 is supplied with deionized water P from a deionized water source (not illustrated). Then, the deionized water P is supplied from the deionized water supply unit 70 to the deionized water passage 31. Therefore, since the deionized water passage 31 has a minute diameter of, for example, 100 μm, the supplied deionized water P is passed in the deionized water passage 31 by the capillary phenomenon.

When the deionize water P is passed to the end of the deionized water passage 31, the deionize water P is further diffused horizontally by the capillary phenomenon. That is, the deionize water P enters a space between the second hydrophilic region 43 and the alignment region 13. Therefore, the deionize water P is filled between the first hydrophilic region 41 and the processing region 12. Further, the deionized water P is diffused between the second hydrophilic region 43 and the alignment region 13, but by the pinning effect of the grooves 42, 14, the deionize water P is not diffused to a region outside the second hydrophilic region 43 and the alignment region 13.

Further, at this time, the template 20 floats with respect to the wafer W by the surface tension of the deionized water P filled between the second hydrophilic region 43 and the alignment region 13. Then, a gap of a predetermined distance H1 is formed between the template 20 and the wafer W. Therefore, the template 20 becomes movable relatively horizontally with respect to the wafer W. Further, at this time, pressure spreads over the entire fluid by Laplace pressure acting on a surface exposed outside the deionized water P between the template 20 and the wafer W. As Pascal's principle, this pressure acts as a force that the template 20 is to float with respect to the wafer W.

Thereafter, in step S3, the restoring force (indicated by an arrow in FIG. 21C) moving the template 20 as illustrated in FIG. 21C is applied to the template 20 by the surface tension of the deionized water P filled between the second hydrophilic region 43 and the alignment region 13 as described above. Then, the alignment of the template 20 and the wafer W is performed by the restoring force. Since the subsequent steps S1 to S4 and S7 are similar to steps S1 to S4 and S7 in the exemplary embodiments as described above, descriptions thereof will be omitted.

According to the present exemplary embodiment, before the plating liquid M is supplied to the processing region 12 of the wafer W, the alignment of the template 20 and the wafer W may also be performed properly by the deionized water P supplied between the second hydrophilic region 43 and the alignment region 13. Accordingly, the plating liquid M may be supplied to the processing region 12 of the wafer W with high positional accuracy, and the plating processing may be properly performed on the wafer W by using the plating liquid M.

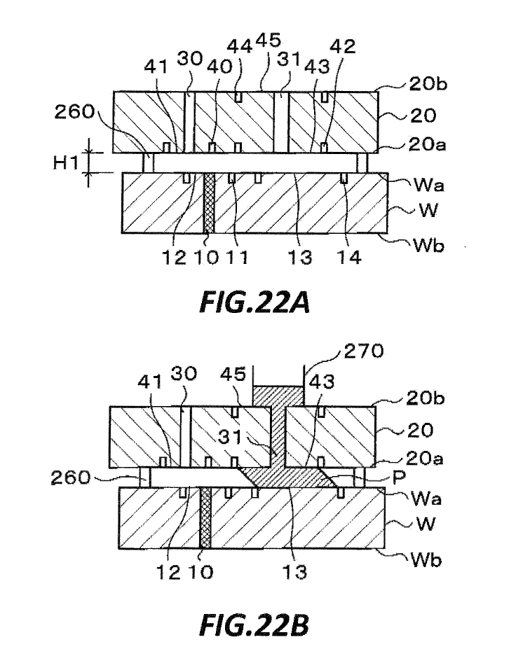

Also in the present exemplary embodiment, elevation mechanisms 260 may be provided in the template 20. In such a case, as illustrated in FIG. 22A, when the template 20 is disposed above the wafer W, the template 20 and the wafer W are supported by the elevation mechanisms 260 therebetween. Then, a distance H1 between the template 20 and the wafer W is maintained to an appropriate distance, for example, 50 μm to 200 μm by the elevation mechanisms 260. Next, as illustrated in FIG. 22B, a gap between the second hydrophilic region 43 and the alignment region 13 is filled with the deionized water P by supplying the deionized water P to the deionized water passage 31 by the deionized water supply unit 270. Subsequently, the elevation mechanisms 260 are reduced such that the template 20 is supported only by the deionized water P. Then, in step S3, a restoring force that moves the template 20 acts on the template 20 by the surface tension of the deionized water P filled between the second hydrophilic region 43 and the alignment region 43 as described above. Then, the alignment of the template 20 and the wafer W is performed by the restoring force. Since the subsequent steps S1 to S4 and S7 are similar to steps S1 to S4 and S7 in the exemplary embodiments as described above, descriptions thereof will be omitted.

According to the present exemplary embodiment, since the distance between the template 20 and the wafer W is adjusted by the elevation mechanisms 260, the time lasting until the template 20 floats may be reduced. Therefore, the wafer processing throughput may be enhanced.

When the distance H1 is very small and the weight of the template 20 is large, the distance H1 may not be maintained properly only by the deionized water P. In such a case, the present exemplary embodiment is particularly useful because the distance H1 may be maintained physically by the elevation mechanisms 260.

In the above exemplary embodiments, the wafer processing has been described with respect to a plating processing in which bumps 110 are formed on through silicon vias 10 of the wafer W. However, the present disclosure may be applied to other wafer processings. For example, the present disclosure may be applied to a case where a plating processing is performed on through holes of a wafer W to form through silicon vias 10.

The present disclosure may also be applied to a case where a processing other than the plating processing is performed on a wafer W by using a processing liquids other than the plating liquid. For example, an etching processing may be performed using an etchant as a processing liquid other than the plating liquid by the method of the present disclosure. Further, an insulation film-forming solution such as, for example, an electro-deposition polyimide solution may be used as other processing liquids to form an insulation film inside openings of a wafer W. Further, a cleaning liquid or deionized water may be used to clean a wafer W.

In the above-described exemplary embodiments, deionized water P is used as an alignment liquid. However, other alignment liquids such as, for example, a plating liquid or an etchant may be used.

From the foregoing, preferred embodiments of the present disclosure were described with reference to the accompanying drawings, but the present disclosure is not limited thereto. It will be appreciated by those skilled in the art that various modifications may be made within the scope of the spirit described in the following claims of the present disclosure. Accordingly, it is understood that their equivalents belong to the technical scope of the present disclosure.

### DESCRIPTION OF SYMBOL

1: wafer processing apparatus
10: through silicon via
11: groove
12: processing region
13: alignment region
14: groove
20: template
20a: front surface
20b: rear surface
30: plating liquid passage
31: deionized water passage
40: groove
41: first hydrophilic region
42: groove
43: second hydrophilic region
44: groove
45: third hydrophilic region
100: control unit
110: bump
200: protrusion
210: protrusion
220: fourth hydrophilic region
221: fifth hydrophilic region
230: hydrophobic region
240: hydrophobic region
250: protrusion
260: elevation mechanism
M: plating liquid
P: deionized water
W: wafer
Wa: front surface
Wb: rear surface

What is claimed is:

1. A substrate processing method of performing a predetermined processing by supplying a processing liquid to a processing region on a surface of a substrate, the method comprising:
supplying an alignment liquid to an alignment region on the surface of the substrate formed at a position different from that of the processing region;
aligning a template disposed facing the substrate and including a processing liquid passage configured to pass the processing liquid and an alignment liquid passage configured to pass the alignment liquid, with respect to the substrate with the alignment liquid supplied to the alignment region such that the processing liquid passage is positioned above the processing region; and
performing the predetermined processing on the substrate by supplying the processing liquid to the processing region through the processing liquid passage.

2. The substrate processing method of claim 1, wherein, when performing the predetermined processing, the template is moved to the substrate side, and then, the processing liquid is supplied to the processing region through the processing liquid passage.

3. The substrate processing method of claim 1, wherein each of the processing region and the alignment region is a hydrophilic region having hydrophilicity.

4. The substrate processing method of claim 3, wherein a groove is formed around the hydrophilic region.

5. The substrate processing method of claim 3, wherein the hydrophilic region protrudes compared to a surrounding region thereof.

6. The substrate processing method of claim 3, wherein a protrusion is formed around the hydrophilic region.

7. The substrate processing method of claim 3, wherein a hydrophobic region having hydrophobicity is formed around the hydrophilic region.

8. The substrate processing method of claim 3, wherein, in the template, each of region corresponding to the processing region and the alignment region has hydrophilicity.

9. The substrate processing method of claim 1, wherein, in the template, the surface facing the substrate is formed with a protrusion in which the processing liquid passage protrudes from a surrounding region thereof.

10. The substrate processing method of claim 1, wherein, when aligning the template and when performing the predetermined processing, an elevation mechanism configured to adjust a relative position between the substrate and the template is used to adjust a distance between the substrate and the template.

11. The substrate processing method of claim 1, wherein, when supplying the alignment liquid, the alignment liquid is supplied to the alignment region, and when aligning the template, the template is disposed facing the substrate and the position of the template is adjusted with respect to the substrate.

12. The substrate processing method of claim 1, wherein, when supplying the alignment liquid, the template is disposed facing the substrate, and the alignment liquid is supplied to the alignment region through the alignment liquid passage.

13. The substrate processing method of claim 1, wherein the alignment liquid is deionized water.

14. A template for use in supplying a processing liquid to a processing region on a surface of a substrate, the template comprising:
a processing liquid passage formed through the template in a thickness direction and configured to pass the processing liquid; and
an alignment liquid passage formed through the template in the thickness direction and configured to pass an alignment liquid that is supplied to an alignment region on the surface of the substrate which is formed at a position different from that of the processing region so as to align the template with respect to the substrate.

15. The template of claim 14, wherein, in the template, each of regions corresponding to the processing region and the alignment region is a hydrophilic region having hydrophilicity, respectively.

16. The template of claim 15, wherein a groove is formed around the hydrophilic region.

17. The template of claim 15, wherein the hydrophilic region protrudes compared to a surrounding region thereof.

18. The template of claim 15, wherein protrusions are formed around the hydrophilic regions.

19. The template of claim 15, wherein the hydrophobic region having hydrophobicity is formed around the hydrophilic region.

20. The template of claim 14, wherein, the surface of the template facing the substrate is formed with a protrusion in which the processing liquid passage protrudes from a surrounding region thereof.

21. The template of claim 14, further comprising an elevation mechanism configured to adjust a relative position between the substrate and the template.

22. The template of claim 14, wherein the alignment liquid is deionized water.
